(19) United States
(12) Patent Application Publication
(10) Pub. No.: US 2007/0113786 A1
(43) Pub. Date: May 24, 2007

(54) Radio frequency grounding rod

(75) Inventor: Chang Sung Ho, Jhongpu Township (TW)

Correspondence Address: John S. Egbert;Egbert Law Offices, 7th Floor, 412 Main Street, Houston, TX, 77002, US

(73) Assignee: CELETECH SEMICONDUCTOR, Inc., Jubei City (TW)

(21) Appl. No.: 11/391,627

(22) Filed: Mar. 28, 2006

(30) Foreign Application Priority Data
Nov. 23, 2005 (TW) 094220283

(51) Int. Cl. C23F 1/00; C23C 16/00

(52) U.S. Cl. 118/723 E; 156/345.47

(57) ABSTRACT

A radio frequency (RF) grounding rod employed in a plasma chamber of semiconductor equipment is disclosed. The RF grounding rod includes a contact head and a main rod. The contact head is electrically connected to an RF mesh of the plasma chamber. The main rod is coated with a conductive layer of gold, silver, nickel, aluminum or copper. One end is connected to the contact head, and the other end is electrically connected to a grounding base of the plasma chamber to form an electrical conductive path. The main rod is formed of an upper rod, a lower rod and connection therebetween. The connection can be formed by soldering gold, silver, nickel, aluminum, copper or the alloy thereof, or by an engagement of a screw portion and a nut portion.

### RELATED U.S. APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### FIELD OF THE INVENTION

The present invention is related to a radio frequency (RF) grounding rod, more specifically, to an RF grounding rod employed in a plasma process chamber.

### BACKGROUND OF THE INVENTION

Plasma is commonly used for wafer manufacturing in the semiconductor industry, e.g., chemical vapor deposition (CVD), physical vapor deposition (PVD) or etching, all using plasma. Plasma contains ionized gases and high-energy electrons generated by ionization of molecules, so that ion bombardment or adsorption occurs on a surface of a wafer to perform etching or deposition. Although plasma could speed up process reaction and lower required process temperature, electrical charges may accumulate and even induce arcing from time to time.

Therefore, the components of the semiconductor process chamber, especially a platform for carrying a wafer, are usually equipped with grounding devices. A dielectric chemical vapor deposition (CVD) chamber is exemplified as follows for explanation.

Dielectric deposition is crucial in the semiconductor process and can form an inter-metal dielectric layer (IMD), a passivation process to prevent the device circuit from being influenced by external moisture and metal ions, or a dielectric anti-reflective coating (DARC) to avoid light reflection in lithography. FIG. 1 illustrates a dielectric deposition system 1 including a process chamber 11, a radio frequency (RF) generator 18, an RF match box 19 and an RF match circuit 19′. The process chamber 111 is configured to perform dielectric deposition, and includes a heater 17 and an anode plate 14. The heater 17 is employed to carry and heat a wafer 16 to be of a process temperature. An RF mesh 10 and an RF grounding rod 13 in the heater 17, and the anode plate 14 are connected as an electrical conduction path so as to generate plasma 15. The RF generator 18, the RF match box 19 and the RF match circuit 19′ form an RF system so as to stably deliver the RF power for generating plasma to the process chamber 11 for dielectric deposition. The surface carrying (in contact with) the wafer 16 of the heater 17 is a ceramic surface (not shown), and the RF mesh 10 is disposed below the ceramic surface and connected to the top of the RF grounding rod 13, whereas the bottom of the RF grounding rod 13 is grounded. A heater resistor (not shown) is provided in the heater 17 to heat the wafer 16 to be of a process temperature (dependent on various processes, usually higher than 200°) for the dielectric deposition on the surface of the wafer 16.

FIG. 2 is a cross-sectional view of the bottom of the heater 17 to show the application of the RF grounding rod 13. An end of the heater 17 secures an end of the RF grounding rod 13 by projected springs 130 in a point-contact manner so as to establish electrical connection therebetween. However, the projected springs 130 are usually exposed in an environment of a high temperature over a long period. As a result, the elastic forces of the projected springs 130 pressing on the end of the RF grounding rod 13 will become weak and may cause fatigue, inducing the contact resistance between them to increase. As a result of higher contact resistance, arcing may occur as an RF power goes therethrough. Not only does the reflected power of the input power become higher, causing unstable manufacturing processing, but also the end of the RF grounding rod 13 is oxidized. Accordingly, the higher resistance due to arcing increases the probability of repeated arcing, and such a vicious cycle seriously affects the yield of the wafers and the equipment has to be shut down for repair.

Moreover, the RF grounding rod 13, or even the entire heater 17, has to be replaced if the RF grounding rod 13 is damaged, so that the lifetime of the heater 17 is shortened and the up-time of the equipment is decreased. Therefore, the cost for wafer manufacturing will be increased.

### BRIEF SUMMARY OF THE INVENTION

The objective of the present invention is to provide an RF grounding rod, more specifically, an RF grounding rod applied in a plasma chamber, which can increase conductive efficiency so as to reduce the probability of arcing. If the RF grounding rod is damaged, it can be reused after being refurbished. Therefore, the manufacturing cost can be tremendously reduced and the up-time of the equipment can be increased.

To achieve the above objective, an RF grounding rod employed in a plasma chamber of semiconductor equipment is disclosed in accordance with the present invention. The RF grounding rod comprises a contact head and a main rod. The contact head is electrically connected to an RF mesh of the plasma chamber. The main rod is coated with a conductive layer of gold, silver, nickel, aluminum or copper. One end is connected to the contact head, and the other end is electrically connected to a grounding base of the plasma chamber to form an electrical conductive path.

In accordance with an embodiment of the present invention, the main rod is constituted of an upper rod, a lower rod and connection means connecting the upper and lower rods. The connection means may be formed by soldering gold, silver, nickel, aluminum, copper or the alloy thereof, or in the form of an engagement of a screw portion and a nut portion.

In view of the design in accordance with the present invention, the damaged portion of the main rod, e.g., the lower rod, can be replaced, and then the entire RF grounding rod is coated with a conductive layer to increase the electrical grounding effect. Therefore, neither the entire RF grounding rod nor the entire heater needs to be replaced, so that the manufacturing cost is reduced and the up-time of the process equipment is increased.

### BRIEF DESCRIPTION OF THE SEVERAL VIEWS OF THE DRAWINGS

FIG. 1 is a schematic view illustrating a known dielectric deposition system.

FIG. 2 is a cross-sectional view of the bottom of the heater shown in FIG. 1.

FIG. 3 is a schematic view illustrating an application of the RF grounding rod in accordance with the present invention.

FIG. 4(a) is a perspective view illustrating a first embodiment of the RF grounding rod in accordance with the present invention.

FIG. 4(b) is the cross-sectional view along line 1-1 in FIG. 4(a).

FIG. 5 is another perspective view illustrating a second embodiment of the RF grounding rod in accordance with the present invention.

FIG. 6 is a perspective view illustrating a third embodiment of the RF grounding rod in accordance with the present invention.

FIGS. 7(a) and 7(b) are perspective and schematic views illustrating a fourth embodiment of the RF grounding rod in accordance with the present invention.

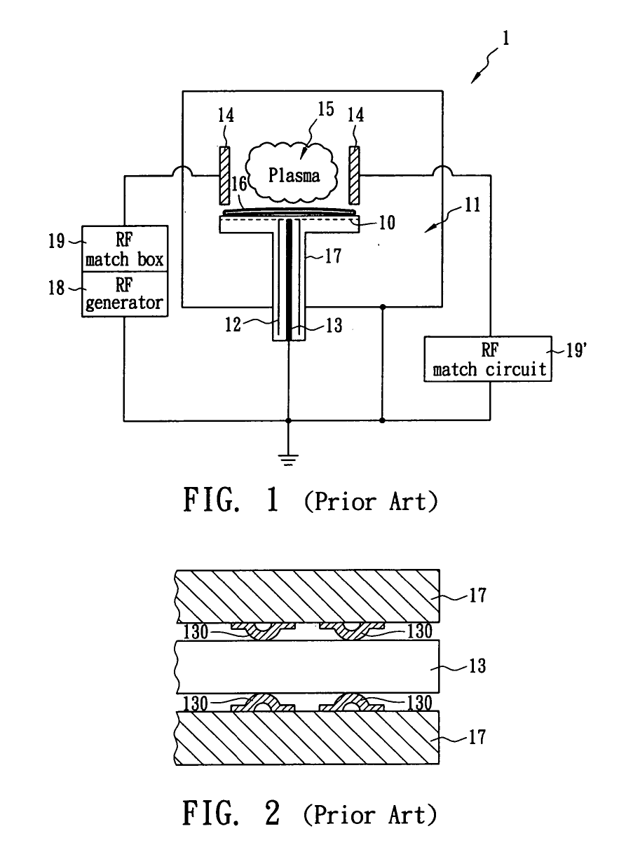

### DETAILED DESCRIPTION OF THE INVENTION

The RF grounding rod of the present invention is described with reference to the appended drawings as follows, so as to clearly show the features of the present invention.

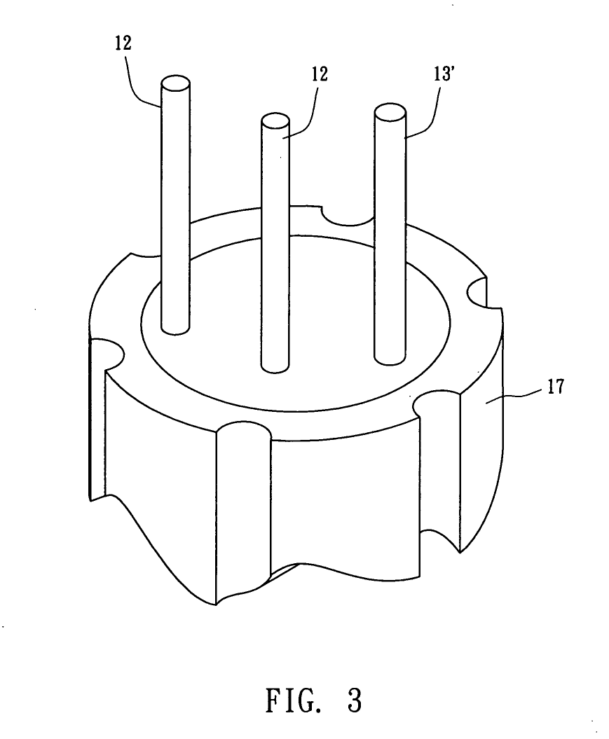

FIG. 3 illustrates an application of an RF grounding rod in accordance with the present invention. The structure shown in FIG. 3 is upside down compared to actual practice for the ease of explanation. An RF grounding rod 13′ is applied in a heater 17 of a plasma chamber, e.g., a chamber for plasma-enhanced chemical vapor deposition (PECVD) in this embodiment. Two heater rods 12 and the RF grounding rod 13′ project out of the bottom of the heater 17.

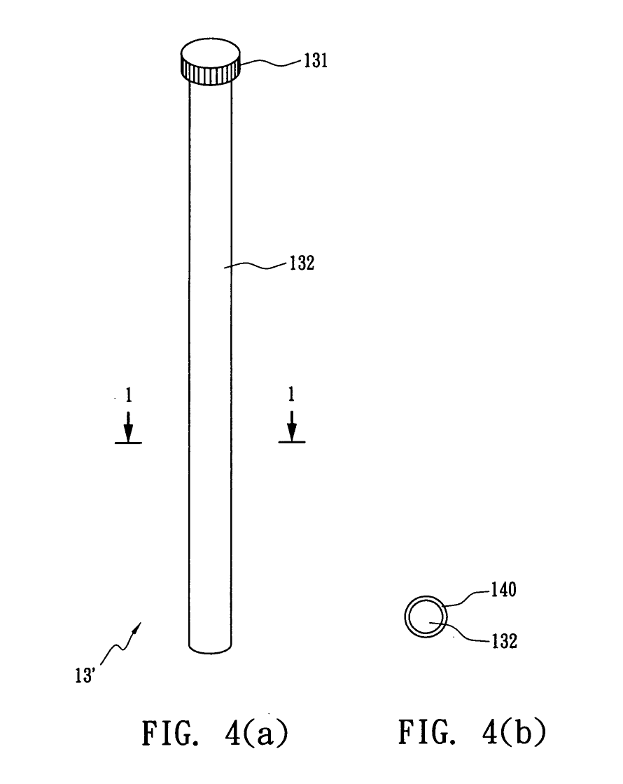

FIG. 4(a) illustrates a structure of the RF grounding rod 13′, and FIG. 4(b) is a cross-sectional view along line 1-1 in FIG. 4(a). The RF grounding rod 13′ comprises a main rod 132 and a contact head 131 connected to the top of the main rod 132. The contact head 131 is employed to be electrically connected to the RF mesh 10, and is in need of high electrical conductivity and high temperature endurance to ground the charges generated by plasma. The contact head 131 can be made of nickel alloy or aluminum alloy. The lower portion of the main rod 132 is secured by the projected springs 130 so as to further guide the charges to a grounding base (not shown) for electrical grounding. The main rod 132 is made of nickel alloy, copper alloy or aluminum alloy, and is coated with a conductive layer 140 made of gold, silver, nickel, aluminum or copper. The thickness of the conductive layer 140 is less than 3 mm. As a result, the conductivity between the main rod 132 and the projected springs 130 is increased, so that the probability of arcing due to inferior contact therebetween can be decreased significantly.

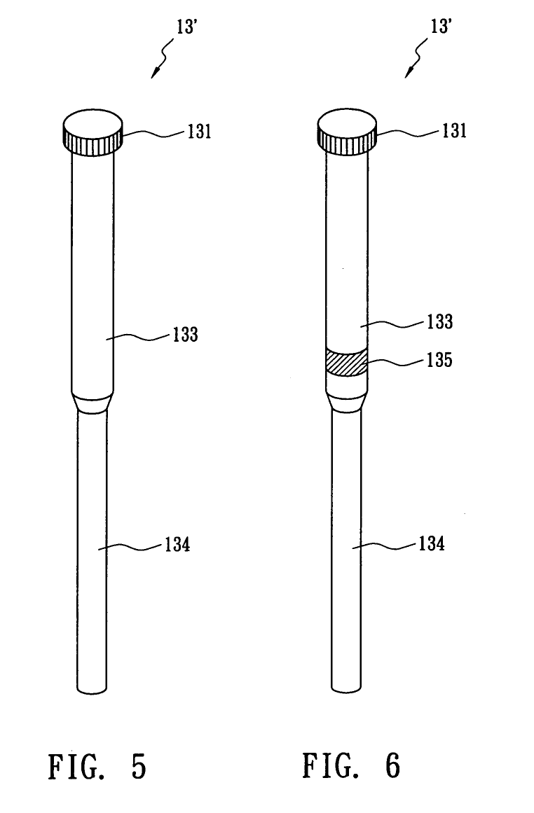

As shown in FIG. 5, the RF grounding rod 13′ may comprise an upper rod 133 and a lower rod 134 with different diameters, and the diameter of the lower rod 134 is less than that of the upper rod 133 by 0.1-4 mm, so that the lower rod 134 can easily protrude from the heater 17.

As shown in FIG. 6, if arcing occurs on the known RF grounding rod 13, the damaged portion by arcing, i.e., the corresponding portion to the lower rod 134 in this embodiment, can be cut off, and then a conductive metal rod is soldered to the bottom of the upper rod 133 as a new lower rod 134, and consequently connection means 135 is formed therebetween. The conductive metal rod can be made of gold, silver, copper or the alloy thereof, and the connection means 135 between the upper rod 133 and the lower rod 134 can be formed by soldering gold, silver, copper, nickel, aluminum or the alloy thereof. Sequentially, the entire rod including the upper rod 133, the connection means and the lower rod 134 is coated with metal, e.g., gold, silver or copper, so as to form an RF grounding rod 13′ of an embodiment of the present invention.

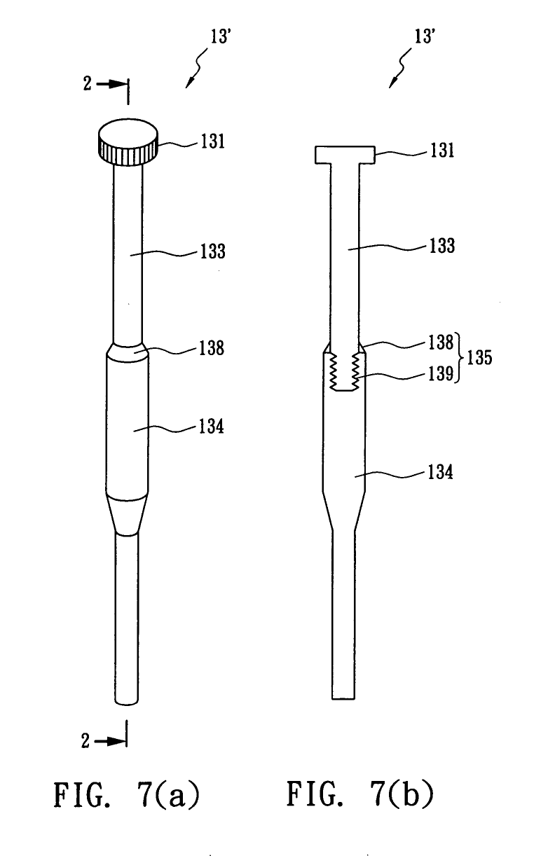

FIG. 7(a) illustrates an RF grounding rod in accordance with another embodiment of the present invention, and FIG. 7(b) is a cross-sectional view along line 2-2 in FIG. 7(a). In addition to the use of soldering, the connection means 135 can be an engagement of a screw portion and a nut portion 139 to connect the upper rod 133 and the lower rod 134. For example, the lower end of the upper rod 133 is provided with a screw portion and the upper end of the lower rod 134 is provided with a corresponding nut portion for engagement. Furthermore, a soldering block 138 can be formed along the circumference of the contact interface by soldering gold, silver, copper, nickel, aluminum or the alloy thereof so as to increase the conductivity. In this embodiment, the lower rod 134 is designed to be a structure including a wider upper portion for accommodating the screw portion and the nut portion 139 and a narrower lower portion of the same diameter for being secured by the projected springs 130.

As mentioned above, the portion of the known RF grounding rod 13 protruding from the bottom of the heater 17 is in contact with the projected springs 130, and arcing occurs thereon from time to time due to the fatigue of the projected springs 130. Therefore, the RF grounding rod 13 often needs to be replaced. Through the design of the connection means 135, if the lower portion of the RF grounding rod 13 is damaged by arcing, the RF grounding rod 13, or even the entire heater 17, does not need to be replaced. Instead, the damaged portion can be directly replaced with a new one and coated with a conductive layer 140. As a result, the cost can be reduced tremendously and the up-time of the process equipment can be increased.

The application of the present invention is not limited to the PECVD process chamber exemplified above, and can be used for other semiconductor process equipment, e.g., CVD, PVD or etching chambers.

The above-described embodiments of the present invention are intended to be illustrative only. Numerous alternative embodiments may be devised by those skilled in the art without departing from the scope of the following claims.

I claim:

1. A radio frequency (RF) grounding rod employed in a plasma chamber, said RF grounding rod comprising:
a contact head electrically connected to an RF mesh of the plasma chamber; and
a main rod coated with an electrical conductive layer, wherein one end of said main rod is connected to said contact head, and wherein another end is electrically connected to a grounding base of the plasma chamber so as to form an electrical conductive path.

2. The radio frequency grounding rod of claim 1, wherein the main rod comprises an upper rod, a lower rod and connection means connecting the upper rod and the lower rod.

3. The radio frequency grounding rod of claim 2, wherein the connection means is comprised of metal connecting the rods by soldering.

4. The radio frequency grounding rod of claim 3, wherein the metal is selected from the group consisting of gold, silver, copper, nickel, aluminum and an alloy thereof.

5. The radio frequency grounding rod of claim 2, wherein the connection means is comprised of an engagement of a screw portion and a nut portion.

6. The radio frequency grounding rod of claim 1, wherein said electrical conductive layer is comprised of gold, silver, copper, nickel, aluminum or an alloy thereof.

7. The radio frequency grounding rod of claim 1, wherein thickness of said electrical conductive layer is less than 3 mm.

8. The radio frequency grounding rod of claim 2, wherein said lower rod comprises an upper portion and a lower portion narrower than said upper portion.

9. The radio frequency grounding rod of claim 1, said main rod being installed in a heater of the plasma chamber.

10. The radio frequency grounding rod of claim 1, wherein the plasma chamber is used for chemical vapor deposition.
